(19) United States
(12) Patent Application Publication
(10) Pub. No.: US 2023/0230222 A1
(43) Pub. Date: Jul. 20, 2023

(54) METHOD AND APPARATUS FOR MEASURING UNIFORMITY OF SIGNAL LINE PATTERN FORMED ON PRINTED CIRCUIT BOARD

(71) Applicant: SMART RADAR SYSTEM, INC., Seongnam-si (KR)

(72) Inventors: Jae Yong LEE, Anyang-si (KR); Yeon Hee SONG, Seoul (KR)

(73) Assignee: SMART RADAR SYSTEM, INC., Seongnam-si (KR)

(21) Appl. No.: 17/578,496

(22) Filed: Jan. 19, 2022

(51) Int. Cl. G06T 7/00; G06T 7/70; G06T 7/60

(52) U.S. Cl. CPC G06T 7/0006; G06T 7/60; G06T 7/70; G06T 2200/24; G06T 2207/10056; G06T 2207/30141

(57) ABSTRACT

Provided is a method of measuring uniformity of a signal line pattern formed on a printed circuit board. The method includes acquiring, by a microscope camera, an image by photographing straight-line shaped dummy signal line patterns formed side by side in a lateral or longitudinal direction on a surface of the outer-layer board, receiving, by a processor included in computing equipment, the image from the microscope camera and marking a first virtual line and a second virtual line, which cross the dummy signal line patterns in the longitudinal direction, on the image, generating, by a user interface included in the computing equipment, intersection points between the first and second virtual lines and the dummy signal line patterns on the image according to manipulation of a measurer, calculating, by the processor, a first distance value between adjacent intersection points located on the first virtual line and a second distance value between adjacent intersection points located on the second virtual line, and measuring, by the processor, uniformity of the signal line pattern on the basis of a difference value between the first distance value and the second distance value.

### BACKGROUND

### 1. Field

The present invention relates to a technique for measuring uniformity of a signal line pattern formed on a printed circuit board.

### 2. Description of Related Art

Signal lines or transmission lines, such as striplines, microstrip lines, co-planar waveguides, and the like, are used to transmit radio frequency (RF) signals with low loss. The characteristic impedance of transmission lines is affected by uniformity of a transmission line. Here, the uniformity of the transmission line refers to the uniformity of a width of the transmission line and the uniformity of a width between adjacent transmission lines.

The uniformity of the transmission line may become a criterion for determining whether a printed circuit board itself on which a transmission line is formed is defective. Conventionally, in order to determine the uniformity of the transmission line, a measurer stays at a level of visually confirming the transmission line through an optical microscope, and thus it is difficult to ensure the reliability of a measurement result.

Further, the characteristic impedance of the transmission line is affected by a surrounding via hole. In particular, the eccentricity of a via hole causes a deviation in characteristic impedance, and there is a concern that an electromagnetic wave reflection loss caused by the deviation in characteristic impedance may increase. Here, as illustrated in FIG. 1, the eccentricity of a via hole refers to a difference 30 between a center 10′ of a via hole 10 and a center 20′ of an annular pad (annular ring) 20 electrically connected to the via hole 10.

When the eccentricity 30 of the via hole is severe, a loss caused by a deviation in characteristic impedance of a transmission line increases, which acts as a factor to reduce electromagnetic wave reception sensitivity or transmission output.

Causes of the eccentricity of a via hole are as follows. A printed circuit board on which an antenna and a transmission line are designed is composed of an inner-layer board and an outer-layer board, and an electromagnetic wave circuit including an antenna and a transmission line is designed on a surface of the outer-layer board. Such a printed circuit board is manufactured by manufacturing the inner-layer board first and then thermocompression bonding the manufactured inner-layer board to the outer-layer board. However, the outer-layer board is made of a low-loss and low-k material such as a Teflon material to reduce a propagation loss, whereas the inner-layer board is made of a material such as flame retardant (FR) 4. The Teflon material and the FR4 material have different stretch rates. Therefore, when the Teflon material and the FR4 material are bonded by thermocompression bonding, the eccentricity occurs between a position of the annular pad (annular ring) 20 connected to the via hole 10 and a position of a drill hole for forming the via hole 10 due to thermal expansion and contraction that is generated during compression. That is, the eccentricity occurs due to an error in mechanical drilling.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

The present invention is directed to providing a method and apparatus for measuring uniformity of a signal line pattern formed on a printed circuit board.

The present invention is also directed to providing a method and apparatus for accurately measuring eccentricity of a via hole with respect to a center of an annular pad (annular ring).

The above-described objects, other objects, advantages, and features of the present invention and methods of achieving the same will be clearly understood with reference to the accompanying drawings and the following detailed embodiments.

In one general aspect, a method of measuring uniformity of a signal line pattern formed on a printed circuit board, which is a method of measuring uniformity of a signal line pattern formed on a printed circuit board including an inner-layer board and an outer-layer board that are bonded by thermocompression bonding, the method includes acquiring, by a microscope camera, an image by photographing straight-line shaped dummy signal line patterns formed side by side in a lateral or longitudinal direction on a surface of the outer-layer board, receiving, by a processor included in computing equipment, the image from the microscope camera and marking a first virtual line and a second virtual line, which cross the dummy signal line patterns in the longitudinal direction, on the image, generating, by a user interface included in the computing equipment, intersection points between the first and second virtual lines and the dummy signal line patterns on the image according to manipulation of a measurer, calculating, by the processor, a first distance value between adjacent intersection points located on the first virtual line and a second distance value between adjacent intersection points located on the second virtual line, and measuring, by the processor, uniformity of the signal line pattern on the basis of a difference value between the first distance value and the second distance value.

In another general aspect, a method of measuring uniformity of a signal line pattern formed on a printed circuit board, which includes acquiring, by a microscope camera, an image by photographing a first dummy signal line pattern having a polygonal shape of a closed loop formed on a surface of the outer-layer board and a second dummy signal line pattern which has the same polygonal shape as the first dummy signal line pattern and surrounds the first dummy signal line pattern at a predetermined distance, receiving, by a processor included in computing equipment, the image from the microscope camera and marking a first virtual line and a second virtual line, which pass through a common central point of the first and second dummy signal line patterns, on the image, generating, by a user interface included in the computing equipment, intersection points between the first and second virtual lines and the first and second dummy signal line patterns on the image according to manipulation of a measurer, calculating, by the processor, a first distance value between adjacent intersection points located on the first virtual line and a second distance value between adjacent intersection points located on the second virtual line, and measuring, by the processor, uniformity of the signal line pattern on the basis of a difference value between the first distance value and the second distance value.

In still another general aspect, an apparatus for measuring uniformity of a signal line pattern formed on a printed circuit board, which includes a microscope camera configured to acquire an image by photographing straight-line shaped dummy signal line patterns formed side by side in a lateral or longitudinal direction on a surface of the outer-layer board, a processor configured to receive the image from the microscope camera and mark a first virtual line and a second virtual line, which cross the dummy signal line patterns in the longitudinal direction, on the image, and a user interface configured to generate intersection points between the first and second virtual lines and the dummy signal line patterns on the image according to manipulation of a measurer, wherein the processor calculates a first distance value between adjacent intersection points located on the first virtual line and a second distance value between adjacent intersection points located on the second virtual line and measures uniformity of the signal line pattern on the basis of a difference value between the first distance value and the second distance value.

In yet another general aspect, an apparatus for measuring uniformity of a signal line pattern formed on a printed circuit board, which includes a microscope camera configured to acquire an image by photographing a first dummy signal line pattern having a polygonal shape of a closed loop formed on a surface of the outer-layer board and a second dummy signal line pattern which has the same polygonal shape as the first dummy signal line pattern and surrounds the first dummy signal line pattern at a predetermined distance, a processor configured to receive the image from the microscope camera and mark a first virtual line and a second virtual line, which pass through a common central point of the first and second dummy signal line patterns on the image, and a user interface configured to generate intersection points between the first and second virtual lines and the first and second dummy signal line patterns on the image according to manipulation of a measurer, wherein the processor calculates a first distance value between adjacent intersection points located on the first virtual line and a second distance value between adjacent intersection points located on the second virtual line and measures uniformity of the signal line pattern on the basis of a difference value between the first distance value and the second distance value.

Other features and aspects will be apparent from the following detailed description, the accompanying drawings, and the claims.

### BRIEF DESCRIPTION OF THE DRAWINGS

FIG. 1 is a diagram for describing problems of the related art.

FIG. 2 is a photograph showing an actually manufactured printed circuit board according to an embodiment of the present invention.

FIG. 3 is a diagram illustrating shapes of a blind via hole (BVH) and a BVH marker formed thereon according to an embodiment of the present invention.

FIG. 4 is a photographic image obtained by actually photographing a region in which the BVH and the BVH marker formed thereon shown in FIG. 2 are formed with an optical microscope.

FIG. 5 shows photographic images obtained by actually photographing a BVH which is eccentric in various directions from a center of a BVH marker hole with an optical microscope according to an embodiment of the present invention.

FIGS. 6 and 7 are photographic images for describing a method of measuring eccentricity of a BVH according to an embodiment of the present invention.

FIG. 8 is a diagram for describing a method of measuring eccentricity of a BVH according to another embodiment of the present invention.

FIG. 9 illustrates diagrams illustrating shapes of dummy signal line patterns according to an embodiment of the present invention.

FIG. 10 illustrates diagrams illustrating shapes of dummy signal line patterns according to another embodiment of the present invention.

FIG. 11 is a diagram for describing a method of measuring uniformity of an actual signal line pattern using straight-line shaped dummy signal line patterns illustrated in FIG. 9.

FIG. 12 is a diagram for describing a method of measuring uniformity of an actual signal line pattern using polygonal dummy signal line patterns illustrated in FIG. 10.

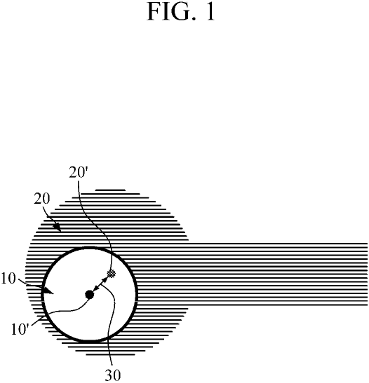

Throughout the accompanying drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

Specific structural and functional descriptions of embodiments of the present invention disclosed in this specification are only for the purpose of describing the embodiments of the present invention, and the embodiments of the present invention may be embodied in various forms and are not to be construed as limited to the embodiments described in this specification.

While the embodiments of the present invention may be modified in various ways and take on various alternative forms, specific embodiments thereof are shown in the accompanying drawings and described in detail in this specification. There is no intent to limit the present invention to the particular forms disclosed. On the contrary, the present invention is to cover all modifications, equivalents, and alternatives falling within the spirit and scope of the appended claims.

The terminology used herein is for the purpose of describing particular embodiments only and is not intended to be limiting to the present invention. As used herein, the singular forms “a” and “an” are intended to also include the plural forms, unless the context clearly indicates otherwise. It should be further understood that the terms “comprise,” “comprising,” “include,” and/or “including,” when used herein, specify the presence of stated features, integers, steps, operations, elements, parts, or combinations thereof, but do not preclude the presence or addition of one or more other features, integers, steps, operations, elements, parts, or combinations thereof.

Hereinafter, embodiments will be described in detail with reference to the accompanying drawings. However, the scope of the patent application is not limited or restricted by these embodiments. Like reference numerals in the accompanying drawings refer to like elements.

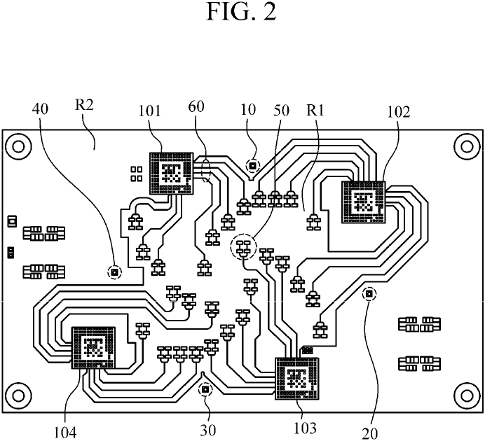

In this specification, an embodiment in which uniformity of a signal line pattern formed on a printed circuit board (PCB) is measured and an embodiment in which eccentricity of a via hole is measured will be mainly described. The embodiment in which the eccentricity of the via hole is measured will be described with reference to FIGS. 2 to 8, and then the embodiment in which the uniformity of the signal line pattern formed on the PCB is measured will be described in detail.

FIG. 2 is a photograph showing an actually manufactured PCB according to an embodiment of the present invention and is for describing positions of a blind via hole (BVH) and a BVH marker.

Referring to FIG. 2, the PCB is divided into an antenna region R1 and a peripheral region R2 surrounding or adjacent to the antenna region R1.

In the antenna region R1, quadrangular patch antennas 50 that are connected to each other like a bunch of grapes and transmission lines that connect the patch antennas 50 to a chip are formed (patterned).

In the antenna region R1 and the peripheral region R2, a region 101 in which the chip is mounted and regions 10, 20, and 30 in which a BVH and a BVH marker formed thereon are formed are defined. The regions 10, 20, and 30, in which the BVH and the BVH marker formed thereon are formed, may be formed in the antenna region R1 or the peripheral region R2.

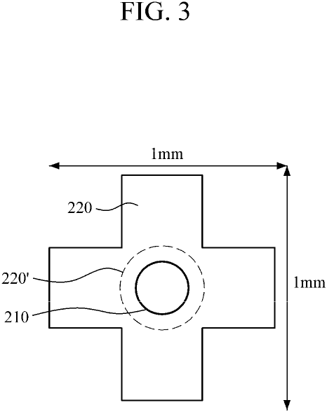

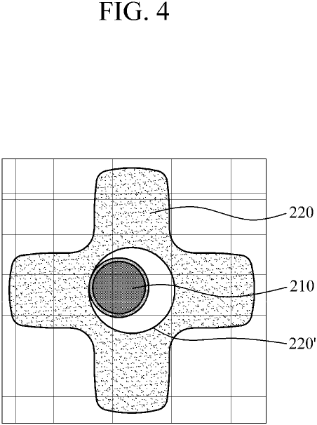

FIG. 3 is a diagram illustrating shapes of a BVH and a BVH marker formed thereon according to an embodiment of the present invention, and FIG. 4 is a photographic image obtained by actually photographing a region in which the BVH and the BVH marker formed thereon shown in FIG. 2 are formed with an optical microscope.

First, referring to FIG. 3, a BVH 210 does not function as an actual via hole but may be a dummy via hole used only for measuring eccentricity of the actual via hole.

Therefore, the BVH 210 is formed in the same process as the actual via hole.

As illustrated in FIG. 3, a BVH marker 220 may be formed on the BVH 210 and may be formed (patterned) in a shape of a cross and made of a copper material.

Further, a circular opening 220′ through which the BVH 210 is exposed upward is formed at a center of the BVH marker 220. Hereinafter, the opening formed at the center of the BVH marker 220 is referred to as a “BVH marker hole” or as a “marker hole” for short.

In FIG. 3, although the cross-shaped BVH marker 220 is shown, the present invention is not limited thereto, and the BVH marker 220 may be patterned in various shapes. For example, the BVH marker 220 may be patterned in one of various polygonal shapes such as a quadrangular shape, a circular shape, a triangular shape, and the like.

When the BVH marker 220 is formed in a cross shape, a quadrangular shape, a circular shape, or a triangular shape, the BVH marker 220 may be designed to have a lateral length of 1 mm and a longitudinal length of 1 mm.

The photographic image shown in FIG. 4 is a photographic image obtained by photographing a situation in which a center of the BVH 210 is eccentric in a nine o′clock direction with respect to a center of the BVH marker hole 220′.

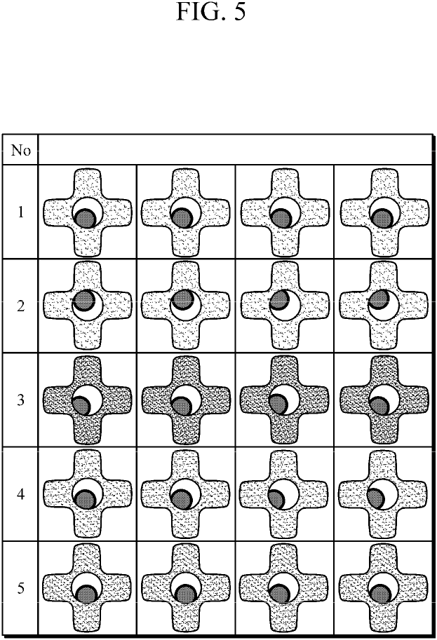

FIG. 5 shows photographic images obtained by actually photographing a BVH which is eccentric in various directions from a center of a BVH marker hole with an optical microscope according to an embodiment of the present invention.

In FIG. 5, No. 1 shows photographs obtained by photographing a situation in which a center of the BVH is eccentric in a seven o′clock direction with respect to a center of the BVH marker hole.

No. 2 shows photographs obtained by photographing a situation in which the center of the BVH is eccentric in an eleven o′clock direction with respect to the center of the BVH marker hole.

No. 3 and 4 show photographs obtained by photographing a situation in which the center of the BVH is eccentric in a seven o′clock direction with respect to the center of the BVH marker hole, that is, a situation in which a degree of the eccentricity is greater than that of No. 1 so that the BVH is more obscured by a BVH marker.

No. 5 shows photographs obtained by photographing a situation in which the center of the BVH is eccentric in a six o′clock direction with respect to the center of the BVH marker hole.

Hereinafter, a method of measuring eccentricity of a BVH will be described in detail.

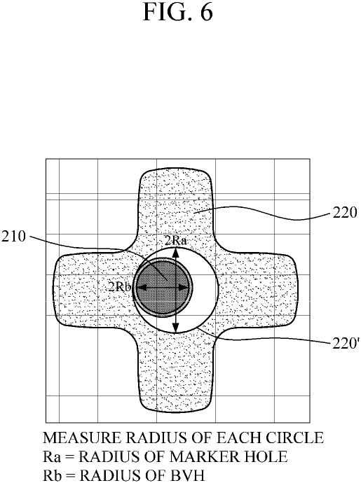

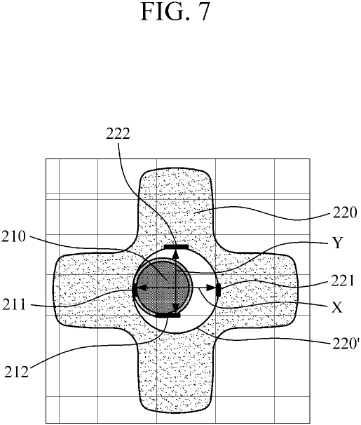

FIGS. 6 and 7 are diagrams for describing a method of measuring eccentricity of a BVH.

First, in order to measure the eccentricity of the BVH, an image of a BVH marker is acquired by photographing the BVH marker formed on a surface of an outer-layer board using a charge-coupled device (CCD) or complementary metal-oxide-semiconductor (CMOS) type microscope camera.

The acquired image is transmitted to computing equipment connected to the microscope camera, and the computing equipment calculates the eccentricity of the BVH from the acquired image. Here, the computing equipment may be a device including a processor, a memory, a display screen, a user interface (mouse, keyboard, etc.), and the like, and the processor may be a central processing unit (CPU) and/or graphics processing unit (GPU) having an arithmetic function for calculating the eccentricity of the BVH.

As shown in FIG. 6, when it is assumed that a radius of a marker hole 220′ of a BVH marker 220 is Ra and a radius of a BVH 210 is Rb, a diameter of the marker hole 220′ becomes 2Ra and a radius of the BVH 210 becomes 2Rb. Ra and Rb are values known in advance. In this case, eccentricities Δx and Δy of the BVH may be calculated using Equation 1 below.

$$\begin{matrix}Δ x = R a + R b - X \\ Δ y = R a + R b - Y\end{matrix}$$

Here, Δx is a value representing the eccentricity in an x-axis direction of the BVH and denotes a distance value from central coordinates in the x-axis direction of the BVH marker hole 220′ to central coordinates in the x-axis direction of the BVH 210.

Δy is a value representing the eccentricity in a y-axis direction of the BVH and denotes a distance value from central coordinates in the y-axis direction of the BVH marker hole 220′ to central coordinates in the y-axis direction of the BVH 210.

X denotes a distance value from an end point 211 of the BVH 210 to an end point 221 of the BVH marker hole 220′ which faces the end point 211. For example, when the end point 211 of the BVH 210 is an end point in a nine o′clock direction as shown in FIG. 7, the end point 221 of the BVH marker hole 220′ may be an end point in a three o′clock direction.

Y denotes a distance value from an end point 212 of the BVH 210 forming a 90° angle with respect to the end point 211 of the BVH 210 to an end point 222 of the BVH marker hole 220′ which faces the end point 212. For example, when the end point 211 of the BVH 210 is an end point in a six o′clock direction, the end point 222 of the BVH marker hole 220′ may be an end point, which faces the end point in the six o′clock direction, in a twelve o′clock direction.

For the X and Y, when a measurer displays a display bar corresponding to each end point on the image using the user interface (mouse or the like), the processor may calculate pixel coordinates corresponding to the display bar and automatically calculate X and Y using the calculated pixel coordinates.

As described above, the computing equipment connected to the microscope camera may measure the eccentricity of the BVH by calculating a separation distance from the central coordinates of the marker hole to the central coordinates of the BVH and a separation direction using the distance between the end point of the marker hole and the end point of the BVH included in the image.

Meanwhile, in the images of FIGS. 6 and 7, the entire circular shape of the BVH 210 is completely exposed upward through the BVH marker hole 220′ of the BVH marker 220, but the degree of eccentricity is severe as shown in No, 3, 4, and 5 of FIG. 5, and thus only a portion of the entire circular shape of the BVH 210 may be exposed upward through the BVH marker hole 220′ of the BVH marker 220. In this case, since the measurer cannot display the display bar corresponding to each end point on the image, the X and Y in Equation 1 above cannot be calculated, and thus the eccentricities Δx and Δy of the BVH cannot be calculated.

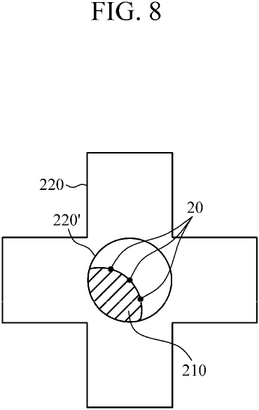

In the above case, as shown in FIG. 8, when the measurer marks at least three marking points 20 on an edge of the BVH 210 that is exposed upward through the BVH marker hole 220′ on the image using a user interface (mouse or the like), the processor may calculate a curvature of the BVH 210 using three pixel coordinates corresponding to the three marking points 20. It is also possible to calculate a curvature of the BVH marker hole 220′ in the same way.

Thereafter, the processor calculates central coordinates of the BVH 210 from the calculated curvature of the BVH 210 and, similarly, calculates central coordinates of the BVH marker hole 220′ from the curvature of the BVH marker hole 220′.

Thereafter, the processor calculates a separation distance and separation direction from the central coordinates of the BVH marker hole 220′ to the central coordinates of the BVH 210 and outputs the calculated separation distance and separation direction as the eccentricities of the BVH 210.

The eccentricity of the BVH 210 obtained in the above manner is provided to PCB manufacturers, and the PCB manufacturers adjust process parameters in PCB manufacturing processes on the basis of the eccentricity of the BVH 210 provided by the measurer.

Hereinafter, a procedure for a method of measuring eccentricity of a BVH formed in a PCB will be described.

First, an inner-layer board is manufactured. A material of the inner-layer board may include, for example, a flame retardant (FR) 4 material. The FR4 may be made of glass fiber and epoxy.

Next, an outer-layer board made of a material having a higher expansion rate than that of the inner-layer board is manufactured. The outer-layer board may include, for example, a Teflon board. Here, the Teflon material may be “polytetrafluoroethylene (PTFE).”

The process of manufacturing the outer-layer board forming a top layer and a bottom layer of the inner-layer board may include a process of forming an actual via hole, a process of forming a BVH for measuring a degree of eccentricity of the actual via hole from a center of an annular pad connected to an upper end of the actual via hole, and a process of forming a BVH marker for exposing an upper end of the BVH upward on a surface of the outer-layer board. Since the present invention is not characterized by limiting specific methods for each process, a description of each process is replaced by known technique.

Next, a process of bonding the inner-layer board and the outer-layer board by thermocompression bonding is performed.

Next, a process of acquiring an image of the BVH marker by photographing the BVH marker formed on the surface of the outer-layer board using a microscope camera is performed.

Next, as described in FIGS. 6 and 7, the process of measuring the eccentricity of the BVH 210 from the image of the BVH marker 220 using computing equipment is performed.

Hereinafter, the process of measuring the eccentricity of the BVH 210 will be described in more detail.

The method of measuring the eccentricity according to the present invention is a method of measuring eccentricity of a BVH 210 formed in a PCB including an inner-layer board and an outer-layer board that are bonded by thermocompression bonding, wherein the method includes acquiring, by a microscope camera, an image by photographing a marker 220 which is formed on a surface of the outer-layer board and a BVH 210 which is exposed upward through a marker hole 220′ formed in a center of the marker 220 with a microscope camera, and measuring, by computing equipment connected to the microscope camera, eccentricity indicating a separation distance and a separation direction from central coordinates of the marker hole 220′ to central coordinates of the BVH 210 using a distance between an end point of the marker hole 220′ and an end point of the BVH 210 which are included in the image.

In an embodiment, the measuring of the eccentricity includes measuring a degree (deviation) to which a center of an actual via hole formed in the outer-layer board is eccentric from a center of an annular pad (annular ring).

In another embodiment, in the measuring of the eccentricity, the end point of the marker hole 220′ may be an end point facing the end point of the BVH 210.

In still another embodiment, in the measuring of the eccentricity, the eccentricities Δx and Δy are calculated using Equation 1 above. In Equation 1 above, Ra denotes a radius of the marker hole, Rb denotes a radius of the BVH, X denotes a distance value from a first end point of the BVH to a first end point of the marker hole which faces the first end point of the BVH, and Y denotes a distance value from a second end point of the BVH forming a 90° angle with respect to the first end point of the BVH to a second end point of the marker hole which faces the second end point of the BVH. Here, when the first end point of the BVH is an end point in a nine o′clock direction of the BVH, the first end point of the marker hole may be an end point in a three o′clock direction of the marker hole. Further, when the second end point of the BVH is an end point in a six o′clock direction of the BVH, the second end point of the marker hole may be an end point in a twelve o′clock direction of the marker hole.

In yet another embodiment, the measuring of the eccentricity includes marking, by a user interface included in the computing equipment, the end point of the marker hole and the end point of the BVH on the image according to the manipulation of the measurer, calculating, by a processor included in the computing equipment, first pixel coordinates corresponding to the end point of the marker hole and second pixel coordinates corresponding to the end point of the BVH, which are marked on the image, and measuring, by the processor, eccentricity using the radius of the marker hole, the radius of the BVH, and the distance value between the first pixel coordinates and the second pixel coordinates.

In yet another embodiment, the measuring of the eccentricity may include measuring, by the processor included in the computing equipment, the eccentricity using a curvature of the BVH and a curvature of the marker hole which appear on the image when only a portion of an entire circular shape of the BVH is exposed upward by the marker. Here, the measuring of the eccentricity using the curvature of the BVH and the curvature of the marker hole which appear on the image includes marking, by the user interface included in the computing equipment, at least three marking points on an edge of the BVH and marking at least three marking points on an edge of the marker hole, which appear on the image according to the manipulation of the measurer, calculating, by the processor included in the computing equipment, the curvature of the BVH using at least three pixel coordinates corresponding to the at least three marking points marked on the edge of the BVH and calculating the curvature of the marker hole using at least three pixel coordinates corresponding to the at least three marking points marked on the edge of the marker hole, extracting, by the processor, the central coordinates of the BVH on the basis of the calculated curvature of the BVH and extracting the central coordinates of the marker hole on the basis of the calculated curvature of the marker hole, and calculating a separation distance value and a separation direction value between the extracted central coordinates of the BVH and the extracted central coordinates of the marker hole and outputting the calculated separation distance value and the separation direction value as the eccentricities.

The method of measuring the eccentricity of a BVH formed in a PCB described so far may be implemented as a computer-readable recording medium in which a program for implementing the method is stored.

Hereinafter, the embodiment in which the uniformity of the signal line pattern is measured will be described in detail.

First, in order to measure the uniformity of the signal line pattern, dummy signal line patterns DP1 and DP2 are formed on the PCB.

The dummy signal line patterns may be formed on the PCB to be disposed in a distributed manner in the peripheral region R2 (see FIG. 2) surrounding the antenna region R1 (see FIG. 2).

The dummy signal line patterns may be referred to as sampling patterns or marker patterns that do not have a signal transmission function, unlike actual signal line patterns, and uniformity of the actual signal line pattern may be estimated by measuring the uniformity of the dummy signal line patterns. That is, the dummy signal line patterns are formed on the PCB in the same process as the actual signal line pattern.

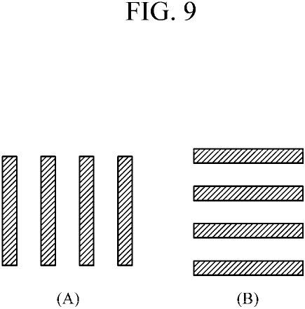

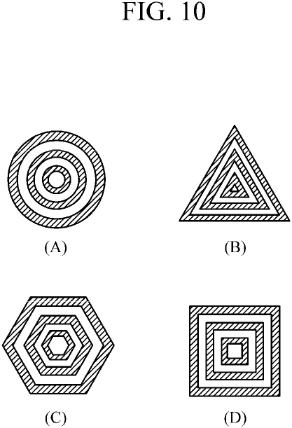

FIG. 9 illustrates diagrams illustrating shapes of dummy signal line patterns according to an embodiment of the present invention, and FIG. 10 illustrates diagrams illustrating shapes of dummy signal line patterns according to another embodiment of the present invention.

In an embodiment, as illustrated in FIG. 9, dummy signal line patterns may have a shape of straight lines formed side by side in a lateral or longitudinal direction on a surface of an outer-layer board of a PCB. FIG. 9A is a diagram illustrating dummy signal line patterns having a shape of straight lines formed side by side in a longitudinal direction, and FIG. 9B is a diagram illustrating dummy signal line patterns having a shape of straight lines formed side by side in a lateral direction.

In another embodiment, as illustrated in FIG. 10, dummy signal line patterns may have a shape of a closed polygonal loop formed on a surface of an outer-layer board of a PCB. FIG. 10A is a diagram illustrating dummy signal line patterns having a circular shape, FIG. 10B is a diagram illustrating dummy signal line patterns having a triangular shape, and FIG. 10C is a diagram illustrating dummy signal line patterns having a hexagonal shape. In addition, FIG. 10D is a diagram illustrating dummy signal line patterns having a quadrangular shape.

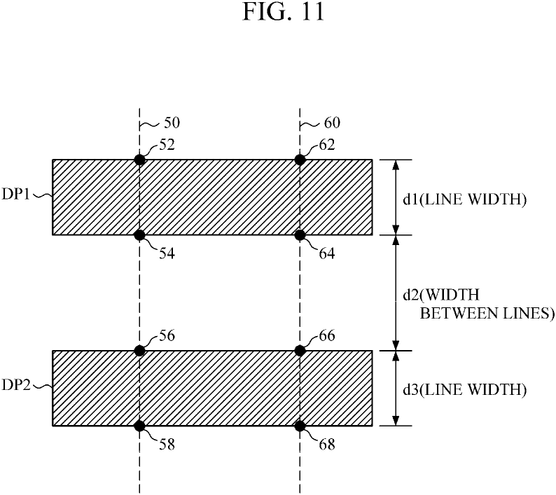

First, a method of measuring uniformity of an actual signal line pattern using the straight-line shaped dummy signal line patterns illustrated in FIG. 9 will be described with reference to FIG. 11.

FIG. 11 is a diagram for describing the method of measuring the uniformity of the actual signal line pattern using the straight-line shaped dummy signal line patterns illustrated in FIG. 9.

Referring to FIG. 11, it is assumed that two dummy signal line patterns DP1 and DP2 are formed on a surface of an outer-layer board in order to simplify the drawing and aid understanding of the description.

First, a microscope camera acquires an image by photographing first and second dummy signal line patterns DP1 and DP2 formed side by side on the surface of the outer-layer board.

Thereafter, a processor included in computing equipment receives the image from the microscope camera and marks first and second virtual lines 50 and 60 crossing the dummy signal line patterns DP1 and DP2 in a longitudinal direction on the image.

Thereafter, a measurer marks intersection points 52, 54, 56, 58, 62, 64, 66, and 68 between first and second virtual lines 50 and 60 and the dummy signal line patterns DP1 and DP2 on the image using a user interface included in the computing equipment.

Thereafter, the processor calculates a first distance value between adjacent intersection points located on the first virtual line 50 and a second distance value between adjacent intersection points located on the second virtual line 60.

Specifically, in the process of calculating the first and second distance values, the processor calculates first pixel coordinates corresponding to the adjacent intersection points located on the first virtual line 50 in the image and calculates second pixel coordinates corresponding to the adjacent intersection points located on the second virtual line 60 in the image. Thereafter, the processor calculates the first distance value between the first pixel coordinates and calculates the second distance value between the second pixel coordinates.

When the adjacent intersection points located on the first virtual line 50 are the intersection points 52 and 54 and the adjacent intersection points located on the second virtual line 60 are the intersection points 62 and 64, the first and second distance values become values representing a line width d1 of the first dummy signal line pattern DP1 illustrated in an upper side of FIG. 11.

Alternatively, when the adjacent intersection points located on the first virtual line 50 are the intersection points 56 and 58 and the adjacent intersection points located on the second virtual line 60 are the intersection points 66 and 68, the first and second distance values become values representing a line width d3 of the second dummy signal line pattern DP2 illustrated in a lower side of FIG. 11.

Alternatively, when the adjacent intersection points located on the first virtual line 50 are the intersection points 54 and 56 and the adjacent intersection points located on the second virtual line 60 are the intersection points 64 and 66, the first and second distance values become values representing a width d2 between lines of the first dummy signal line pattern DP1 and the second dummy signal line pattern DP2.

Therefore, when a difference between the first distance value and the second distance value is less than or equal to a tolerance value, this means that the line widths d1 and d3 of the dummy signal line patterns DP1 and DP2 or the width d2 between lines of the dummy signal line patterns DP1 and DP2 are uniform and, accordingly, it can be estimated that the actual signal line pattern patterned in the same process as the dummy signal line patterns DP1 and DP2 is uniform.

Specifically, in the method of measuring the uniformity of the signal line pattern, for example, the processor compares a difference value between the first distance value and the second distance value with a preset tolerance value. When the difference value is less than or equal to the tolerance value, the processor determines that the uniformity of the signal line pattern is high and outputs a result of the determination (good PCB), and when the difference value exceeds the tolerance value, the processor determines that the uniformity of the signal line pattern is low (defective PCB) and outputs a result of the determination.

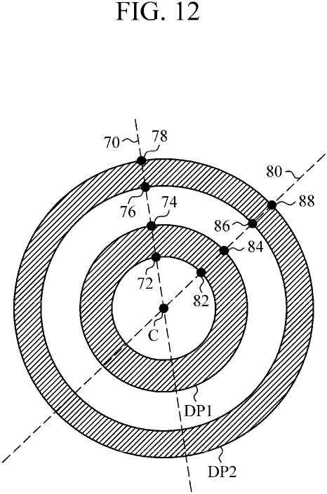

Hereinafter, a method of measuring uniformity of an actual signal line pattern using dummy signal line patterns having a polygonal shape of a closed loop illustrated in FIG. 10 will be described with reference to FIG. 12.

FIG. 12 is a diagram for describing a method of measuring uniformity of an actual signal line pattern using the polygonal dummy signal line patterns illustrated in FIG. 10.

Referring to FIG. 12, it is assumed that two circular dummy signal line patterns DP1 and DP2 are formed on a surface of an outer-layer board in order to simplify the drawing and aid understanding of the description. In this case, the circular second dummy signal line pattern DP2 is patterned on the surface of the outer-layer board to surround the circular first dummy signal line pattern DP1 at a predetermined distance based on one common central point C in design.

First, a microscope camera acquires an image by photographing the first dummy signal line pattern DP1 and the second dummy signal line pattern DP2 surrounding the first dummy signal line pattern DP1.

Next, a processor included in computing equipment receives the image from the microscope camera and marks first and second virtual lines 70 and 80 passing through the common central point C of the first and second dummy signal line patterns DP1 and DP2 on the image. Here, the common central point C of the first and second dummy signal line patterns DP1 and DP2 may be found by calculating a curvature of the first or second dummy signal line pattern DP1 or DP2. For example, when the measurer marks at least three points on edges of the first or second dummy signal line pattern DP1 or DP2 on the image using a user interface (mouse or the like), the processor may calculate three pixel coordinates on the image, which correspond to the three points, and calculate central coordinates of the corresponding circular dummy signal line pattern using the three pixel coordinates. It can be said that this method is the same as the method of calculating the central coordinates of the BVH described above.

Next, when the first and second virtual lines 70 and 80 are marked on the image, the measurer marks intersection points 72, 74, 76, 78, 82, 84, 86, and 88 between the first and second virtual lines 70 and 80 and the first and second dummy signal line patterns DP1 and DP2 on the image using the user interface.

Next, the processor calculates a first distance value between adjacent intersection points [72, 74], [74, 76], and [76, 78] located on the first virtual line 70 and a second distance value between adjacent intersection points [82, 84], [84, 86], and [86, 88] located on the second virtual line 80. The process of calculating the first and second distance values is the same as the process of calculating the first and second distance values described with reference to FIG. 11. Therefore, a description thereof will be omitted.

Next, the processor measures the uniformity of the signal line pattern on the basis of a difference value between the first distance value and the second distance value. The process of measuring the uniformity of the signal line pattern is also the same as the process of measuring the uniformity of the signal line pattern described with reference to FIG. 11. Therefore, a description thereof will be omitted.

The above-described embodiments should be considered from an exemplary point of view for description rather than a limiting point of view. In particular, in this specification, all of the BVHs, the markers, and the dummy signal line patterns are described as being formed on one PCB. However, when the present invention only aims to measure the uniformity of the signal line pattern, the process of patterning the BVHs and the markers on the PCB is not required. Conversely, when the present invention only aims to measure the eccentricity of the via hole, the process of patterning the dummy signal line patterns on the PCB is not required.

Further, in the present invention, all the straight-line shaped and polygonal dummy signal line patterns for measuring the uniformity of the signal line pattern may be patterned on a surface of one board.

According to the present invention, by allowing computing equipment to measure uniformity of a dummy signal line pattern corresponding to an actual signal line pattern formed on a PCB, the uniformity of the actual signal line pattern can be accurately measured.

Further, eccentricity of a BVH can be calculated using a BVH that does not function as an actual via hole in a PCB and a BVH marker formed thereon and process parameters set in the manufacturing process of the PCB can be adjusted based on the calculated eccentricity, and thus it is possible to reduce an electromagnetic wave reflection loss caused by the eccentricity of the via hole.

The scope of the present invention is indicated in the claims rather than the foregoing description, and all differences within the scope equivalent thereto should be construed as being included in the present invention.

What is claimed is:

1. A method of measuring uniformity of a signal line pattern formed on a printed circuit board including an inner-layer board and an outer-layer board that are bonded by thermocompression bonding, the method comprising:
acquiring, by a microscope camera, an image by photographing straight-line shaped dummy signal line patterns formed side by side in a lateral or longitudinal direction on a surface of the outer-layer board;
receiving, by a processor included in computing equipment, the image from the microscope camera and marking a first virtual line and a second virtual line, which cross the dummy signal line patterns in the longitudinal direction, on the image;
generating, by a user interface included in the computing equipment, intersection points between the first and second virtual lines and the dummy signal line patterns on the image according to manipulation of a measurer;
calculating, by the processor, a first distance value between adjacent intersection points located on the first virtual line and a second distance value between adjacent intersection points located on the second virtual line; and
measuring, by the processor, uniformity of the signal line pattern on the basis of a difference value between the first distance value and the second distance value.

2. The method of claim 1, wherein each of the first and second distance values is a line width of one dummy signal line pattern.

3. The method of claim 1, wherein each of the first and second distance values is a width between lines of adjacent dummy signal line patterns.

4. The method of claim 1, wherein the calculating of the first distance value and the second distance value includes:
calculating first pixel coordinates corresponding to the adjacent intersection points located on the first virtual line;
calculating second pixel coordinates corresponding to the adjacent intersection points located on the second virtual line;
calculating a first distance value between the first pixel coordinates; and
calculating a second distance value between the second pixel coordinates.

5. The method of claim 1, wherein the measuring of the uniformity of the signal line pattern includes:
comparing a difference value between the first distance value and the second distance value with a preset tolerance value; and
outputting a result obtained by comparing the difference value with the tolerance value as a result obtained by measuring the uniformity of the signal line pattern.

6. The method of claim 5, wherein the outputting of the result includes:
when the difference value is less than or equal to the tolerance value, determining that the uniformity of the signal line pattern is high and outputting a result of the determination; and
when the difference value exceeds the tolerance value, determining that the uniformity of the signal line pattern is low and outputting a result of the determination.

7. A method of measuring uniformity of a signal line pattern formed on a printed circuit board including an inner-layer board and an outer-layer board that are bonded by thermocompression bonding, the method comprising:
acquiring, by a microscope camera, an image by photographing a first dummy signal line pattern having a polygonal shape of a closed loop formed on a surface of the outer-layer board and a second dummy signal line pattern which has the same polygonal shape as the first dummy signal line pattern and surrounds the first dummy signal line pattern at a predetermined distance;
receiving, by a processor included in computing equipment, the image from the microscope camera and marking a first virtual line and a second virtual line, which pass through a common central point of the first and second dummy signal line patterns, on the image;
generating, by a user interface included in the computing equipment, intersection points between the first and second virtual lines and the first and second dummy signal line patterns on the image according to manipulation of a measurer;
calculating, by the processor, a first distance value between adjacent intersection points located on the first virtual line and a second distance value between adjacent intersection points located on the second virtual line; and
measuring, by the processor, uniformity of the signal line pattern on the basis of a difference value between the first distance value and the second distance value.

8. The method of claim 7, wherein the polygonal shape includes a triangular shape, a quadrangular shape, a pentagonal shape, a hexagonal shape, and a circular shape.

9. The method of claim 7, wherein the first and second distance values are line widths of the first and second dummy signal line patterns, respectively.

10. The method of claim 7, wherein each of the first and second distance values is a width between lines of the first and second dummy signal line patterns.

11. The method of claim 7, wherein the calculating of the first distance value and the second distance value includes:
calculating first pixel coordinates corresponding to the adjacent intersection points located on the first virtual line;
calculating second pixel coordinates corresponding to the adjacent intersection points located on the second virtual line;
calculating a first distance value between the first pixel coordinates; and
calculating a second distance value between the second pixel coordinates.

12. The method of claim 7, wherein the measuring of the uniformity of the signal line pattern includes:
comparing a difference value between the first distance value and the second distance value with a preset tolerance value; and
outputting a result obtained by comparing the difference value with the tolerance value as a result obtained by measuring the uniformity of the signal line pattern.

13. The method of claim 1, wherein the method further comprising:
acquiring, by the microscope camera, a second image by photographing a marker which is formed on the surface of the outer-layer board and a blind via hole which is exposed upward through a marker hole formed in a center of the marker; and
measuring, by the processor, eccentricity indicating a distance from central coordinates of the marker hole to central coordinates of the blind via hole using a distance between an end point of the marker hole and an end point of the blind via hole which are included in the second image.

14. The method of claim 13, wherein, in the measuring of the eccentricity, the eccentricity (Δx, Δy) is calculated using Equations below:
$$\text{Δ} x = R a + R b - X$$
$$\text{Δ} y = R a + R b - Y ,$$
wherein Ra denotes a radius of the marker hole, Rb denotes a radius of the blind via hole, X denotes a distance value from a first end point of the blind via hole to a first end point of the marker hole which faces the first end point of the blind via hole, and Y denotes a distance value from a second end point of the blind via hole forming a 90° angle with respect to the first end point of the blind via hole to a second end point of the marker hole which faces the second end point of the blind via hole.

15. The method of claim 13, wherein, when the first end point of the blind via hole is an end point in a nine o′clock direction of the blind via hole, the first end point of the marker hole is an end point in a three o′clock direction of the marker hole.

16. The method of claim 13, wherein the measuring of the eccentricity includes:
marking, by the user interface, the end point of the marker hole and the end point of the blind via hole on the second image according to manipulation of a measurer;
calculating, by the processor included in the computing equipment, first pixel coordinates corresponding to the end point of the marker hole and second pixel coordinates corresponding to the end point of the blind via hole which are marked on the second image; and
measuring, by the processor, the eccentricity using the radius of the marker hole, the radius of the blind via hole, and the distance value between the first pixel coordinates and the second pixel coordinates.

17. The method of claim 13, wherein the calculating of the first distance value and the second distance value includes:
calculating first pixel coordinates corresponding to the adjacent intersection points located on the first virtual line;
calculating second pixel coordinates corresponding to the adjacent intersection points located on the second virtual line;
calculating a first distance value between the first pixel coordinates; and
calculating a second distance value between the second pixel coordinates.

18. An apparatus for measuring uniformity of a signal line pattern formed on a printed circuit board including an inner-layer board and an outer-layer board that are bonded by thermocompression bonding, the apparatus comprising:
a microscope camera configured to acquire an image by photographing straight-line shaped dummy signal line patterns formed side by side in a lateral or longitudinal direction on a surface of the outer-layer board;
a processor configured to receive the image from the microscope camera and mark a first virtual line and a second virtual line, which cross the dummy signal line patterns in the longitudinal direction, on the image; and
a user interface configured to generate intersection points between the first and second virtual lines and the dummy signal line patterns on the image according to manipulation of a measurer,
wherein the processor calculates a first distance value between adjacent intersection points located on the first virtual line and a second distance value between adjacent intersection points located on the second virtual line and measures uniformity of the signal line pattern on the basis of a difference value between the first distance value and the second distance value.

19. An apparatus for measuring uniformity of a signal line pattern formed on a printed circuit board including an inner-layer board and an outer-layer board that are bonded by thermocompression bonding, the apparatus comprising:
a microscope camera configured to acquire an image by photographing a first dummy signal line pattern having a polygonal shape of a closed loop formed on a surface of the outer-layer board and a second dummy signal line pattern which has the same polygonal shape as the first dummy signal line pattern and surrounds the first dummy signal line pattern at a predetermined distance;
a processor configured to receive the image from the microscope camera and mark a first virtual line and a second virtual line, which pass through a common central point of the first and second dummy signal line patterns on the image; and
a user interface configured to generate intersection points between the first and second virtual lines and the first and second dummy signal line patterns on the image according to manipulation of a measurer,
wherein the processor calculates a first distance value between adjacent intersection points located on the first virtual line and a second distance value between adjacent intersection points located on the second virtual line and measures uniformity of the signal line pattern on the basis of a difference value between the first distance value and the second distance value.
